(19) United States
(12) Patent Application Publication
(10) Pub. No.: US 2026/0107078 A1
(43) Pub. Date: Apr. 16, 2026

(54) AD CONVERSION CIRCUIT, PHOTOELECTRIC CONVERSION DEVICE, IMAGE CAPTURING DEVICE, MOVING BODY, AND METHOD OF DRIVING AD CONVERSION CIRCUIT

(71) Applicant: CANON KABUSHIKI KAISHA, Tokyo (JP)

(72) Inventors: MASANORI FURUTA, Kanagawa (JP); TAKUYA KURIHARA, Kanagawa (JP)

(21) Appl. No.: 19/360,047

(22) Filed: Oct. 16, 2025

(30) Foreign Application Priority Data
Oct. 16, 2024 (JP) 2024-181234

(51) Int. Cl. H04N 25/78; H03M 3/00; H04N 25/60

(52) U.S. Cl. CPC H04N 25/78; H03M 3/438; H03M 3/496; H04N 25/60

(57) ABSTRACT

An AD conversion circuit is provided. The circuit includes a ΔΣ AD converter including an integrator to integrate a difference signal, a switch to perform switching to supply an analog signal supplied to an input terminal to the ΔΣ AD converter in a first period and supply a voltage signal corresponding to a voltage output from the integrator at an end of the first period to the ΔΣ AD converter in a second period after the first period, and a holding circuit to hold the voltage signal corresponding to a voltage output from the integrator at the end of the first period and provide the voltage signal to the ΔΣ AD converter via the switch in the second period. The integrator includes a continuous-time integrator and a discrete-time integrator connected to an output of the continuous-time integrator.

### BACKGROUND

### Field of the Technology

The present disclosure relates to an AD conversion circuit, a photoelectric conversion device, an image capturing device, a moving body, and a method of driving an AD conversion circuit.

### Description of the Related Art

There is known an analog/digital converter (ADC) that converts an analog signal as a pixel output from a solid-state image capturing device into a digital signal. A ΔΣ ADC is known as an ADC. Japanese Patent Laid-Open No. 2017-005716 discloses a ΔΣ ADC using a loop filter that connects a continuous-time integrator and a discrete-time integrator. Using the continuous-time integrator on the preceding stage of the loop filter makes it possible to achieve a reduction in noise by band-limiting the analog signal input to the ΔΣ ADC. In addition, using a discrete-time integrator on the subsequent stage of the loop filter makes it possible to suppress noise caused by clock jitter causing a problem in the continuous-time integrator and suppress characteristic fluctuation caused by manufacture variation of passive elements such as capacitors as compared with a case where only the continuous-time integrator is used. S. Tao et. al., “A Power-Efficient Continuous-Time Incremental Sigma-Delta ADC for Neural Recording Systems”, IEEE Transactions on Circuits and Systems I: Regular Papers (Volume: 62, Issue: 6, June 2015) (to be referred to as “S. Tao” hereinafter) discloses a 2-stage continuous-time ΔΣ ADC as a technique that speeds up a two-dimensional continuous-time ΔΣ ADC. This 2-stage continuous-time ΔΣ ADC includes cascaded ADCs, one for performing AD conversion corresponding to a high-order bit string and the other for performing AD conversion corresponding to a low-order bit string upon receiving the residual voltage of the ADC corresponding to high-order bits as an input.

### SUMMARY

A 2-stage ΔΣ ADC including a loop filter that connects a continuous-time integrator and a discrete-time integrator is potentially effective as a technique of implementing an increase in AD conversion speed while suppressing noise and characteristic fluctuation. On the other hand, the 2-stage ΔΣ ADC disclosed in S. Tao requires an ADC that performs AD conversion corresponding to a high-order bit string and an ADC that performs AD conversion corresponding to a low-order bit string and hence requires a large circuit packaging area.

Some embodiments of the present disclosure provide a technique advantageous in reducing the circuit size of a ΔΣ AD conversion circuit.

According to some embodiments, an AD conversion circuit that converts an analog signal provided to an input terminal into a digital signal, the AD conversion circuit comprising: a ΔΣ AD converter including an integration circuit configured to integrate a difference signal; a switching circuit configured to perform switching to supply an analog signal supplied to the input terminal to the ΔΣ AD converter in a first period and supply a voltage signal corresponding to a voltage output from the integration circuit at an end of the first period to the ΔΣ AD converter in a second period after the first period; and a holding circuit configured to hold the voltage signal corresponding to a voltage output from the integration circuit at the end of the first period and provide the voltage signal to the ΔΣ AD converter via the switching circuit in the second period, wherein the integration circuit includes a continuous-time integrator and a discrete-time integrator connected to an output of the continuous-time integrator, is provided.

According to some other embodiments, a method of driving an AD conversion circuit configured to convert an analog signal provided to an input terminal into a digital signal, the AD conversion circuit comprising: a ΔΣ AD converter including an integration circuit configured to integrate a difference signal; a holding circuit; and a switching circuit configured to switch between connection between the input terminal and the ΔΣ AD converter and connection between the holding circuit and the ΔΣ AD converter, the method comprising: causing the switching circuit to connect between the input terminal and the ΔΣ AD converter to supply an analog signal supplied to the input terminal to the ΔΣ AD converter and causing the holding circuit to hold a voltage signal corresponding to a voltage output from the integration circuit; and causing the switching circuit to connect between the holding circuit and the ΔΣ AD converter to supply a voltage signal held by the holding circuit at an end of the causing the switching circuit between the input terminal and the ΔΣ AD converter to the ΔΣ AD converter after the causing the switching circuit between the input terminal and the ΔΣ AD converter, wherein the integration circuit includes a continuous-time integrator and a discrete-time integrator connected to an output of the continuous-time integrator, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram showing an example of the arrangement of an AD conversion circuit according to the present embodiment;

FIG. 2 is a timing chart showing the operation timing of the AD conversion circuit in FIG. 1;

FIG. 3 is a block diagram showing an example of the arrangement of a second-order hybrid ΔΣ AD converter of the AD conversion circuit in FIG. 1;

FIG. 4 is a circuit diagram showing an example of the arrangement of the second-order hybrid ΔΣ AD converter of the AD conversion circuit in FIG. 1;

FIG. 5 is a circuit diagram showing another example of the integrator of the ΔΣ AD converter of the AD conversion circuit in FIG. 1;

FIG. 6 is a circuit diagram showing an example of the arrangement of the 4-input comparator of the AD conversion circuit in FIG. 1;

FIGS. 7A and 7B are views showing another example of the integrator of the ΔΣ AD converter in FIG. 3;

FIG. 8 is a circuit diagram showing an example of the arrangement of the residual voltage holding circuit of the AD conversion circuit in FIG. 1;

FIG. 9 is a view showing an example of the operation of the residual voltage holding circuit of the AD conversion circuit in FIG. 1;

FIG. 10 is a circuit diagram showing an example of the arrangement of the AD conversion circuit according to the present embodiment;

FIG. 11 is a circuit diagram showing an example of the arrangement of a buffer circuit having a voltage holding function for the AD conversion circuit in FIG. 10;

FIGS. 12A and 12B are views showing an example of the arrangement and the operation timing of a buffer circuit having a voltage holding function for the AD conversion circuit in FIG. 10;

FIG. 13 is a circuit diagram showing an example of the arrangement of the AD conversion circuit according to the present embodiment;

FIG. 14 is a circuit diagram showing an example of the arrangement of the second-order hybrid ΔΣ AD converter of the AD conversion circuit in FIG. 13;

FIG. 15 is a circuit diagram showing an example of the arrangement of the second-order hybrid ΔΣ AD converter of the AD conversion circuit in FIG. 13;

FIG. 16 is a circuit diagram showing an example of the arrangement of the voltage regulating circuit of the AD conversion circuit in FIG. 13;

FIG. 17 is a circuit diagram showing an example of the arrangement of the AD conversion circuit according to the present embodiment;

FIG. 18 is a block diagram showing an example of the arrangement of a photoelectric conversion device including the AD conversion circuit according to the present embodiment;

FIG. 19 is a block diagram showing an example of the arrangement of a photoelectric conversion system including the AD conversion circuit according to the present embodiment; and

FIGS. 20A and 20B are views showing an example of the arrangement of a moving body including the AD conversion circuit according to the present embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

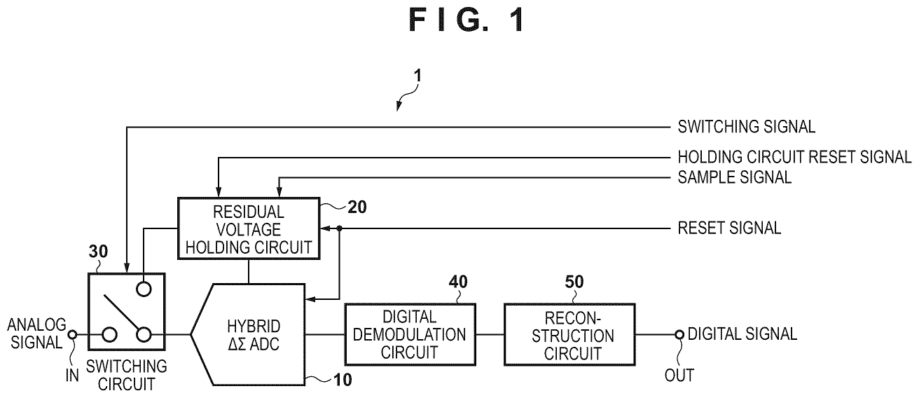

An analog/digital (AD) conversion circuit according to an embodiment of the present disclosure will be described with reference to FIGS. 1 to 17. FIG. 1 shows the arrangement of an AD conversion circuit 1 according to the first embodiment of the present disclosure. The AD conversion circuit 1 is configured as a 2-stage ΔΣ AD conversion circuit. The AD conversion circuit 1 converts the analog signal provided to an input terminal IN into a digital signal and outputs the digital signal from an output terminal OUT. The AD conversion circuit 1 can include a ΔΣ AD converter 10 and a switching circuit 30 (the ΔΣ AD converter is sometimes written as a ΔΣ ADC). The AD conversion circuit 1 can also include a residual voltage holding circuit 20, a digital demodulation circuit 40, and a reconstruction circuit 50. The ΔΣ AD converter 10 can include an integration circuit that integrates a difference signal. In a first period, the switching circuit 30 supplies the analog signal supplied to the input terminal IN to the ΔΣ AD converter 10. The switching circuit 30 supplies a voltage signal corresponding to the voltage output from the integration circuit of the ΔΣ AD converter 10 at the end of the first period to the ΔΣ AD converter 10 in the second period after the first period. The first period is a period in which AD conversion is performed to generate a high-order bit string of a digital signal corresponding to the analog signal provided to the input terminal IN. The second period is a period in which AD conversion is performed to generate a low-order bit string of a digital signal corresponding to the analog signal provided to the input terminal IN. The high-order bit string can be constituted by a plurality of bits. The low-order bit string can be constituted by a plurality of bits.

The residual voltage holding circuit 20 holds (samples) a voltage signal corresponding to the residual voltage output from the ΔΣ AD converter 10 at the end of the first period and provides the voltage signal to the switching circuit 30 in the second period. The residual voltage holding circuit 20 can be controlled by, for example, a holding circuit reset signal and a sample signal.

In the first period, the ΔΣ AD converter 10 performs AD conversion corresponding to a high-order bit string, and the switching circuit 30 supplies a voltage signal corresponding to the residual voltage held by the residual voltage holding circuit 20 at the end of the first period to the ΔΣ AD converter 10. Subsequently, in the second period, the ΔΣ AD converter 10 performs AD conversion corresponding to a low-order bit string. The digital demodulation circuit 40 demodulates the ΔΣ modulated signal (high-order bit string) output from the ΔΣ AD converter 10 in the first period into a digital signal having a plurality of bits. In addition, the digital demodulation circuit 40 demodulates the ΔΣ modulated signal (low-order bit string) output from the ΔΣ AD converter 10 in the second period into a digital signal having a plurality of bits. The reconstruction circuit 50 generates an output digital signal based on the digital signal of the high-order bit string and the digital signal of the low-order bit string, which are demodulated by the digital demodulation circuit 40. An internal signal in the ΔΣ AD converter 10 and an internal signal in the digital demodulation circuit 40 are reset before the start of the first period and before the start of the second period in accordance with reset signals. This arrangement can implement the AD conversion circuit 1 as a 2-stage ΔΣ AD conversion circuit by using the ΔΣ AD converter 10 and the residual voltage holding circuit 20. That is, the circuit size of the ΔΣ AD conversion circuit is reduced.

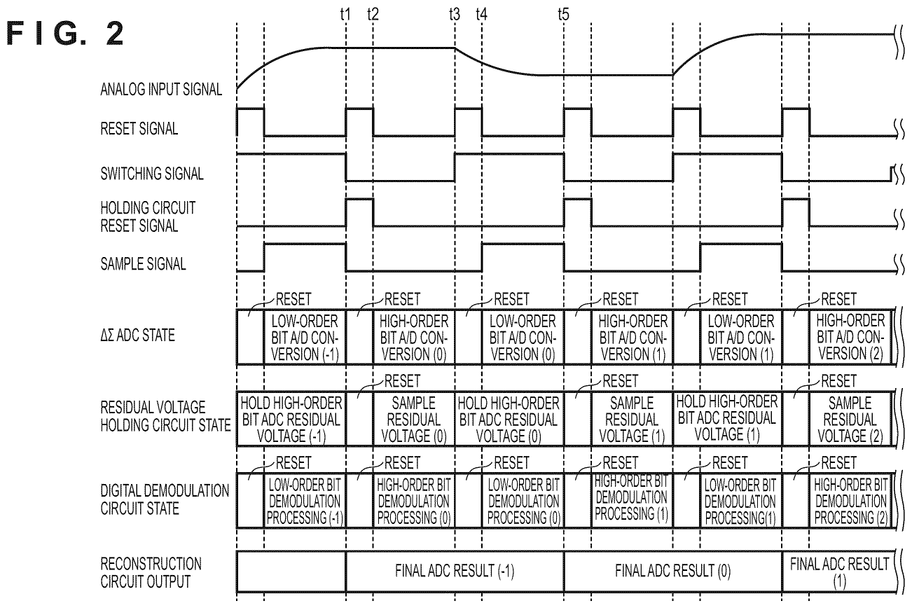

FIG. 2 shows the operation timing of the AD conversion circuit 1 shown in FIG. 1. A processing procedure in which the reconstruction circuit 50 outputs a final ADC result (0) will be described as an operation example of the 2-stage AD conversion circuit 1.

In a period from time t1 to time t2, a reset signal is set to high level to reset the ΔΣ AD converter 10 and the digital demodulation circuit 40. At the same time, a holding circuit reset signal is set to high level to reset the residual voltage holding circuit 20. At time t2, from the time point when the reset signal transitions to low level, the ΔΣ AD converter 10 starts AD conversion corresponding to high-order bits, and the residual voltage holding circuit 20 starts to sample a residual voltage. In addition, the digital demodulation circuit 40 starts demodulation processing of the high-order bits. At time t3, after the end of the AD conversion corresponding to the high-order bits, the residual voltage holding circuit 20 starts to hold the residual voltage of the ΔΣ AD converter 10. At the same time, the reconstruction circuit 50 acquires a multi-bit modulated signal corresponding to the high-order bits.

Subsequently, in a period from time t3 to time t4, the reset signal is set to high level again to reset the ΔΣ AD converter 10 and the digital demodulation circuit 40. At time t4, from the time point when the reset signal transitions to low level, the ΔΣ AD converter 10 starts AD conversion corresponding to the low-order bits. In addition, the digital demodulation circuit 40 starts the demodulation processing of the low-order bits. At time t5, after the end of the AD conversion corresponding to the low-order bits, the reconstruction circuit 50 acquires a multi-bit demodulated signal corresponding to the low-order bits. Thereafter, the reconstruction circuit 50 performs reconstruction processing by using the multi-bit demodulated signal corresponding to the high-order bits and the multi-bit demodulated signal corresponding to the low-order bits. With this processing, the final AD conversion result corresponding to the digital output signal is output. The 2-stage AD conversion circuit 1 performs ΔΣ AD conversion with respect to an arbitrary analog input signal by repeating the above AD conversion procedure. In this case, assume that an input analog signal in an AD conversion period corresponding to the above high-order bit string is constant.

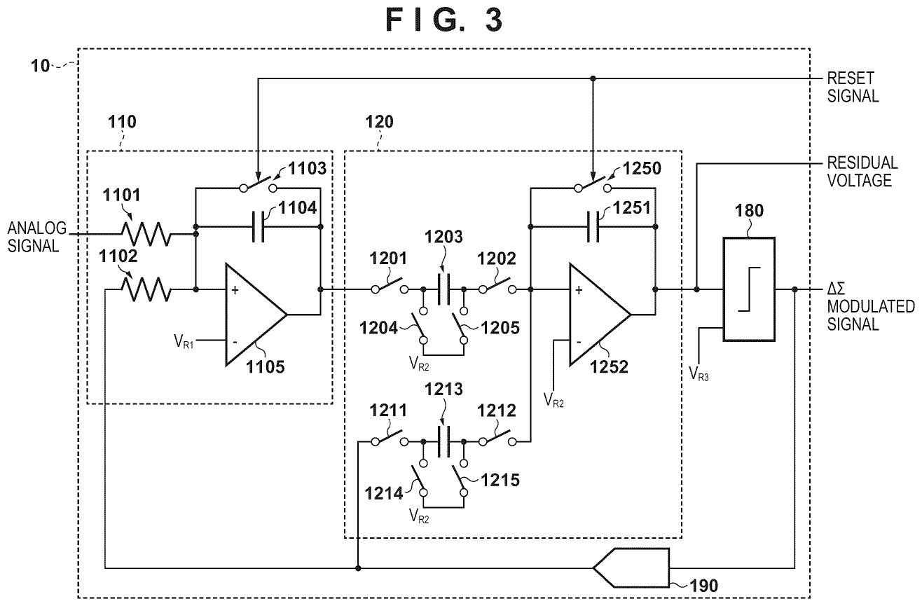

FIG. 3 shows the circuit arrangement of the second-order hybrid ΔΣ AD converter as a detailed arrangement example of the ΔΣ AD converter 10. More specifically, the ΔΣ AD converter 10 has a second-order hybrid arrangement including, as integration circuits, a continuous-time integrator 110 and a discrete-time integrator 120 connected to the output of the continuous-time integrator 110. The ΔΣ AD converter 10 also includes a comparator 180 that compares an output from the discrete-time integrator 120 with a reference signal and a digital/analog converter (DA converter) 190 connected to the output of the comparator 180. An output from the DA converter 190 is supplied to a resistor 1102 of the continuous-time integrator 110 and a switch 1211 of the discrete-time integrator 120. Reference symbols V_{R1} to V_{R3} shown in FIG. 3 denote, for example, reference voltages such as the ground potential. Although the arrangement shown in FIG. 3 is configured to supply different reference voltages in the respective circuit blocks, the voltage V_{R1} to V_{R3} may be the same voltage.

The continuous-time integrator 110 can be configured to include a resistors 1101 and 1102, a capacitor 1104, a switch 1103, and an amplifier 1105. The discrete-time integrator 120 can be configured to include capacitors 1203, 1213, and 1251, switches 1201, 1202, 1204, 1205, 1211, 1212, 1214, 1215, and 1250, and an amplifier 1252. The capacitor 1203 and the switches 1201, 1202, 1204, and 1205 constitute a sampling circuit connected to the output of the continuous-time integrator 110. In addition, the capacitor 1213 and the switches 1211, 1212, 1214, and 1215 constitute a sampling circuit connected to the output of the DA converter 190. As the capacitors described in this specification, those formed as capacitive elements can be suitably used. For example, it is possible to use, for example, a metal-insulator-semiconductor (MIS) type capacitor, a metal-insulator-metal (MIM) type capacitor, and a metal-oxide-metal (MOM) type capacitor. The forms of these capacitive elements are an example, and any elements functioning as capacitors can be used as needed.

In the ΔΣ AD converter 10 shown in FIG. 3, the capacitors 1104 and 1251 are reset when a reset signal is at high level. When the reset signal is at low level, the continuous-time integrator 110 integrates the difference signal between the analog signal input to the ΔΣ AD converter 10 and an output from the DA converter 190. In addition, the discrete-time integrator 120 integrates the difference signal between an output from the continuous-time integrator 110 and an output from the DA converter 190 by using a clock signal (not shown). Upon receiving the difference signal between an output from the discrete-time integrator 120 and a reference signal (the reference voltage V_{R3}), the comparator 180 performs a comparing operation by using a clock signal (not shown). The DA converter 190 outputs an analog voltage in accordance with an output signal from the comparator 180. The DA converter 190 can be configured to output an analog voltage corresponding to an input signal in accordance with a 1-bit transfer function indicated by equation (1):

$$DACout ( DACin ) = \{ \begin{matrix}Vr , & ( DACin = 1 ) \\ 0 , & ( DACin = 0 )\end{matrix} \qquad ( 1 )$$

where DACin is an output signal from the comparator 180, Vr is a reference signal (not shown) in the ΔΣ AD converter 10, and DACout is an output signal from the DA converter 190. The reference signal is 0. The second-order hybrid ΔΣ AD converter 10 shown in FIG. 3 repeatedly performs an integrating operation, a comparing operation, and digital/analog conversion in a period from when a reset signal is set to low level to when the reset signal is set to high level.

In the arrangement example shown in FIG. 3, the AD conversion circuit 1 is configured as a second-order hybrid ΔΣ AD converter. In the arrangement example shown in FIG. 3, in the AD converter 10, both the comparator 180 and the DA converter 190 have 1-bit configurations. However, the comparator 180 and the DA converter 190 may have multi-bit configurations, and circuits equivalent to the resistor 1102 of the continuous-time integrator 110, the switches 1211, 1212, 1214, and 1215 of the discrete-time integrator 120, and the capacitor 1213 may be increased in number in accordance with the resolution of the comparator 180 and the DA converter 190, and the circuits may be connected in parallel. Making the comparator 180 and the DA converter 190 have multi-bit configurations makes it possible to increase the A/D conversion speed of the ΔΣ AD converter 10. A third-order or higher order hybrid ΔΣ AD converter may be configured by adding one or more discrete-time integrators between the discrete-time integrator 120 and the comparator 180. Increasing the number of integrators can increase the A/D conversion speed of the hybrid ΔΣ AD converter 10.

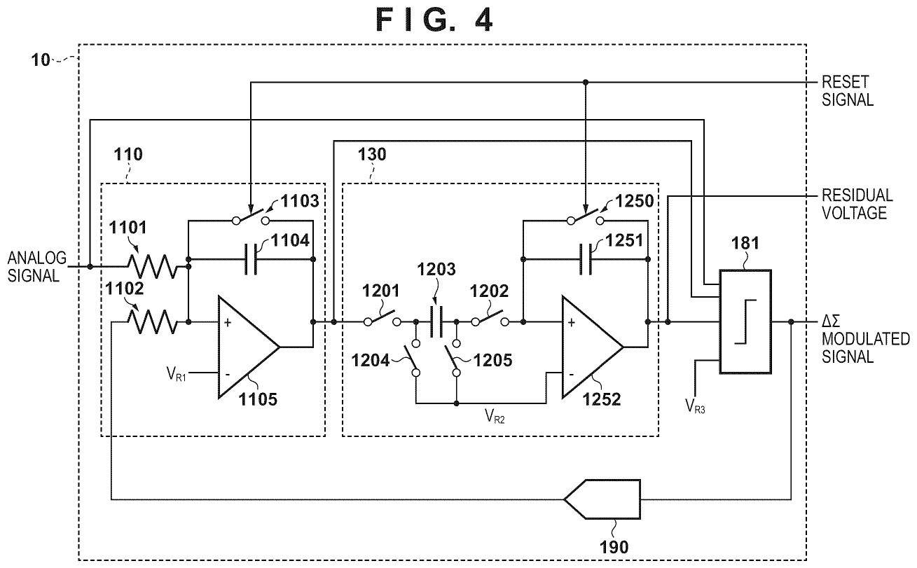

FIG. 4 shows the second-order hybrid ΔΣ AD converter 10 having a feedforward path as an arrangement example different from the arrangement of the ΔΣ AD converter 10 shown in FIG. 3. The ΔΣ AD converter 10 shown in FIG. 4 can include the continuous-time integrator 110, a discrete-time integrator 130, a 4-input comparator 181, and the DA converter 190. The continuous-time integrator 110 can be configured to include the resistors 1101 and 1102, the capacitor 1104, the switch 1103, and the amplifier 1105. The discrete-time integrator 130 can be configured to include the capacitors 1203 and 1251, the switches 1201, 1202, 1204, 1205, and 1250, and the amplifier 1252. The capacitor 1203 and the switches 1201, 1202, 1204, and 1205 constitute a sampling circuit connected to the output of the continuous-time integrator 110.

In addition to an output from the discrete-time integrator 130 and a reference signal (the reference voltage V_{R3}), an output from the continuous-time integrator 110 and the analog signal supplied to the continuous-time integrator 110 are supplied to comparator 181. Accordingly, the comparator 181 compares the output from the continuous-time integrator 110 and the analog signal supplied to the continuous-time integrator 110, in addition to the output from the discrete-time integrator 130, with the reference signal. The output from the comparator 181 is supplied to the DA converter 190, and the output from the DA converter 190 is supplied to the resistor 1102 of the continuous-time integrator 110. Reference symbols V_{R1} to V_{R3} shown in FIG. 3 denote, for example, reference voltages such as the ground potential. Although the arrangement shown in FIG. 3 is configured to supply different reference voltages in the respective circuit blocks, the voltage V_{R1} to V_{R3} may be the same voltage.

The operation of the AD conversion circuit 1 including the ΔΣ AD converter 10 shown in FIG. 4 is similar to that of the AD conversion circuit 1 including the ΔΣ AD converter 10 shown in FIG. 3. In the arrangement shown in FIG. 4, a signal input to the ΔΣ AD converter 10 is supplied to the 4-input comparator 181. This makes it possible to suppress the amplitudes of the signals output from the continuous-time integrator 110 and the discrete-time integrator 130 and suppress the nonlinear influences of the amplifier 1105 and the amplifier 1252. This can improve the nonlinear strain characteristics of the ΔΣ AD converter 10.

In the arrangement example shown in FIG. 4, the AD conversion circuit 1 is configured as a second-order hybrid ΔΣ AD conversion circuit. In addition, in the arrangement example shown in FIG. 4, in the ΔΣ AD converter 10, both the comparator 181 and the DA converter 190 have 1-bit configurations. However, the comparator 181 and the DA converter 190 may have multi-bit configurations, and the resistor 1102 of the continuous-time integrator 110 may be increased in number in accordance with the resolution of the comparator 181 and the DA converter 190, and the resistors may be connected in parallel. Making the comparator 181 and the DA converter 190 have multi-bit configurations makes it possible to increase the A/D conversion speed of the ΔΣ AD converter 10. A third-order or higher order hybrid ΔΣ AD converter may be configured by adding one or more discrete-time integrators between the discrete-time integrator 120 and the comparator 181. Increasing the number of integrators can increase the A/D conversion speed of the hybrid ΔΣ AD converter 10.

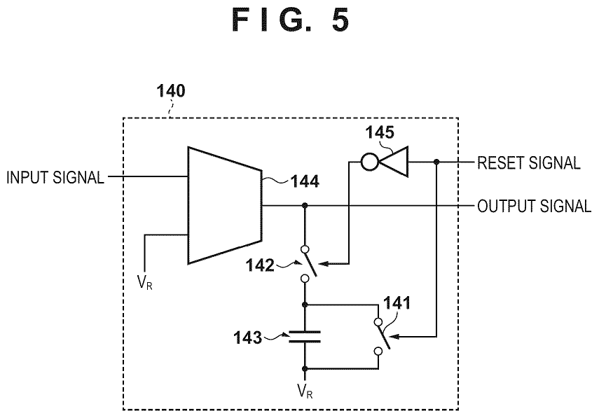

FIG. 5 shows a Gm-C integrator 140 as another example of the arrangement of the continuous-time integrator in the ΔΣ AD converter 10. The Gm-C integrator 140 can include switches 141 and 142, a capacitor 143, a transconductor 144, and an inverter 145. Reference symbol V_{R} shown in FIG. 5 denotes, for example, a reference voltage such as the ground potential. The switch 141 is controlled by a reset signal. The switch 142 is controlled by the reset signal inverted by the inverter 145. When the reset signal is at high level, the capacitor 143 is reset by discharging the accumulated electric charge. When the reset signal is at low level, an integrating operation is performed by using the difference current between the current generated by the transconductor 144 and an output signal current from the DA converter 190 and the capacitor 143 in accordance with an input signal. If the Gm-C integrator 140 is used as the continuous-time integrator of the ΔΣ AD converter 10, the output of the DA converter 190 is connected to the output of the transconductor 144. This arrangement can reduce the power consumption while implementing the same function as an integrator constituted by a resistor, a capacitor, and an amplifier.

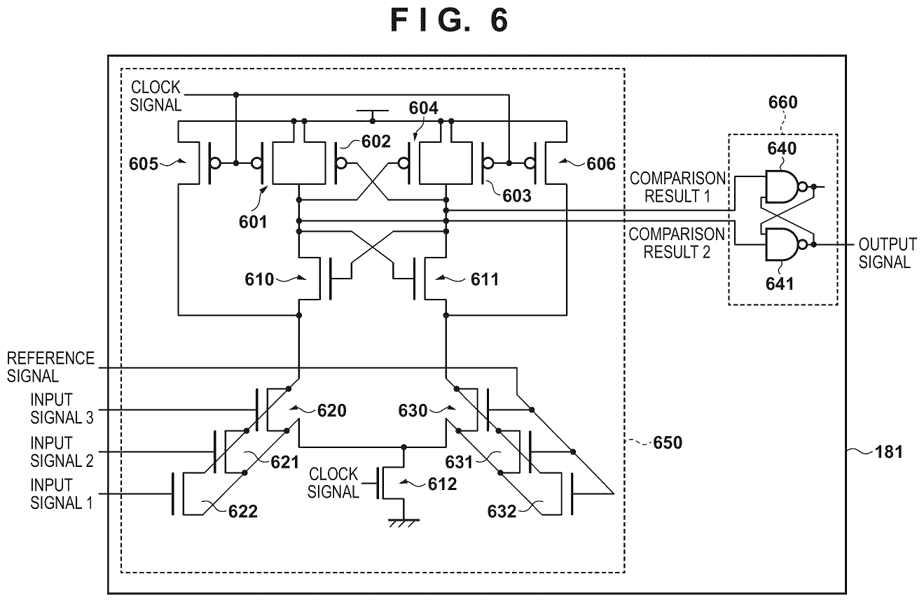

FIG. 6 shows an example of the arrangement of the 4-input comparator 181. The comparator 181 can be configured to include a latch-type comparator 650 and an SR flip-flop 660. The latch-type comparator 650 can be configured to include, for example, PMOS transistors 601, 602, 603, 604, and 605, NMOS transistors 610, 611, and 612, and NMOS transistors 620, 621, 622, 630, 631, and 632. The SR flip-flop 660 can be configured to include NAND gates 640 and 641. According to the arrangement example shown in FIG. 6, in the 4-input comparator 181, when a clock signal is at low level, the latch-type comparator 650 is set in a reset state, comparison results 1 and 2 as output signals are set to high level, and the SR flip-flop 660 is set in a held state. When the clock signal is at high level, the latch-type comparator 650 respectively generates internal signals corresponding to difference voltages with respect to a reference signal with respect to three input signals and outputs results corresponding to the generated internal signals as comparison results 1 and 2. In addition, the SR flip-flop 660 outputs signals corresponding to comparison results 1 and 2. In the 4-input comparator 181, if the sum voltage of input signal 1-reference signal, input signal 2-reference signal, and input signal 3-reference signal is, for example, a positive voltage, comparison results 1 and 2 are respectively set to low level and high level, and the output signal is set to high level.

The arrangement example shown in FIG. 6 exemplifies the 4-input comparator 181, in which input signals are respectively connected to the NMOS transistors 620, 621, 622, 630, 631, and 632. Increasing the number of such transistors functioning as input transistors can implement an arrangement corresponding to a third-order or higher order ΔΣ AD converter. Although FIG. 6 shows the arrangement configured to input three input signals and a reference signal, the arrangement may be configured to input three input signals each serving as a difference signal without any reference signal.

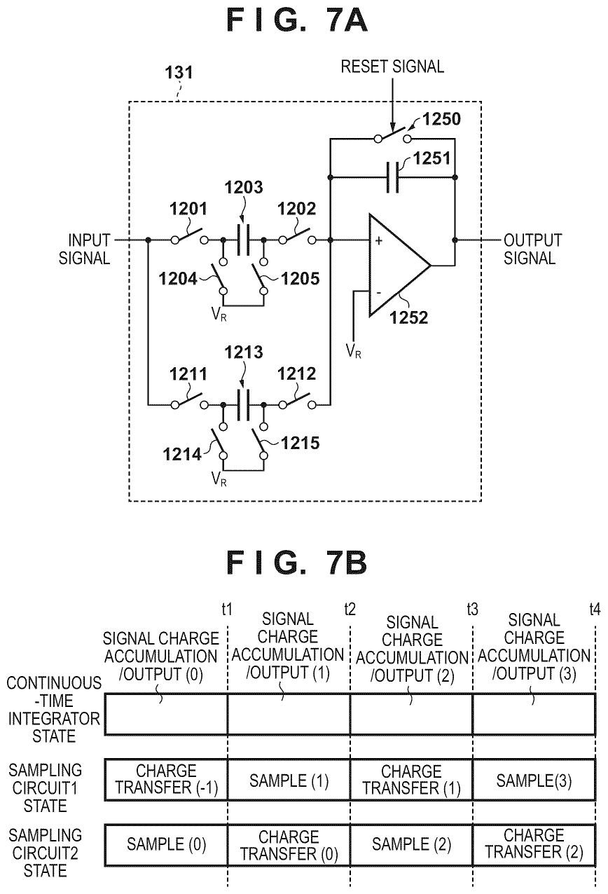

FIG. 7A shows an example of the arrangement of a discrete-time integrator 131 having an arrangement different from that of the discrete-time integrator 130 shown in FIG. 4. FIG. 7B shows an example of the operation of the discrete-time integrator 131. The discrete-time integrator 131 can be configured to include the capacitors 1203, 1213, and 1251, the switches 1201, 1202, 1204, 1205, 1211, 1212, 1214, 1215, and 1250, and the amplifier 1252. The discrete-time integrator 131 includes a sampling circuit 1 configured to include the capacitor 1203 and the switches 1201, 1202, 1204, and 1205 and a sampling circuit 2 configured to include the capacitor 1213 and the switches 1211, 1212, 1214, and 1215. Reference symbol V_{R} in FIG. 7A denotes a reference voltage such as the ground potential. The sampling circuits 1 and 2 are connected to the output of the continuous-time integrator 110.

In the sampling circuit 1, one main terminal of the switch 1201 and one main terminal of the switch 1204 are connected to one main terminal of the capacitor 1203, and one main terminal of the switch 1205 and one main terminal of the switch 1202 are connected to the other main terminal of the capacitor 1203. The other main terminal of the switch 1204 and the other main terminal of the switch 1205 are connected to the reference voltage V_{R}. In the sampling circuit 2, one main terminal of the switch 1211 and one main terminal of the switch 1214 are connected to one main terminal of the capacitor 1213, and one main terminal of the switch 1215 and one main terminal of the switch 1212 are connected to the other main terminal of the capacitor 1213. The other main terminal of the switch 1214 and the other main terminal of the switch 1215 are connected to the reference voltage V_{R}.

The sampling circuit 1 samples an input signal when the switches 1201 and 1205 are in the ON (conductive) state, and the switches 1202 and 1204 are in the OFF (nonconductive) state. In addition, the sampling circuit 1 transfers the sampled electric charge to the capacitor 1251 when the switches 1201 and 1205 are in the OFF state, and the switches 1202 and 1204 are in the ON state. In the discrete-time integrator 131, the switch 1211 of the sampling circuit 2 is also connected to the input signal. The operation of the sampling circuit 2 is almost the same as that of the sampling circuit 1, but the operations of the switches 1211 and 1215 are reverse to those of the switches 1201 and 1205 of the sampling circuit 1. Likewise, the operations of the switches 1212 and 1214 of the sampling circuit 2 are reverse to those of the switches 1202 and 1204 of the sampling circuit 1.

The circuit operation of the sampling circuit 1 and the sampling circuit 2 will be described with reference to the timing chart of FIG. 7B. The circuit operation in which an output signal from the continuous-time integrator 110 is input to the discrete-time integrator 131 will be described hereinafter. In a period from time t1 to time t2, the sampling circuit 1 of the discrete-time integrator 131 samples an output signal (1) from the continuous-time integrator 110. In a period from time t2 to time t3, the electric charge sampled in the sampling circuit 1 is transferred to the capacitor 1251 of the integrator, and an integrating operation is performed. In the same period from time t2 to time t3, the sampling circuit 2 of the discrete-time integrator 131 samples an output signal (2) from the continuous-time integrator 110. Subsequently, in a period from time t3 to time t4, the electric charge sampled in the sampling circuit 2 is transferred to the capacitor 1251 of the integrator, and an integrating operation is performed. In this manner, outputs from the continuous-time integrator 110 are alternately sampled by the sampling circuit 1 and the sampling circuit 2. The discrete-time integrator 131 can also be regarded as performing an interleaving operation during a time in which output signals from the continuous-time integrator 110 are complementarily sampled and accumulated by using the two sampling circuits 1 and 2. This operation enables the discrete-time integrator 131 to reduce power in the amplifier 1252 as compared with the discrete-time integrator 130 shown in FIG. 4.

In this case, the present embodiment is not limited to this form. For example, capacitors are added among the other main terminal of the switch 1202 (the main terminal that is not connected to the capacitor 1203 of the switch 1202), the other main terminal of the switch 1212 (the main terminal that is not connected to the capacitor 1213 of the switch 1212), and the input terminal of the amplifier 1252. In addition, one main terminal of the switch 1250 is connected to the input terminal of the amplifier 1252, and the other main terminal of the switch 1250 is connected to the output terminal of the amplifier 1252. Furthermore, one main terminal of the capacitor 1251 is connected to the other main terminal of the switch 1202 and the other main terminal of the switch 1212, and the other main terminal of the capacitor 1251 is connected to the output terminal of the amplifier 1252. This arrangement can accurately reduce an offset component during the accumulation operation of the amplifier 1252 in the discrete-time integrator 131.

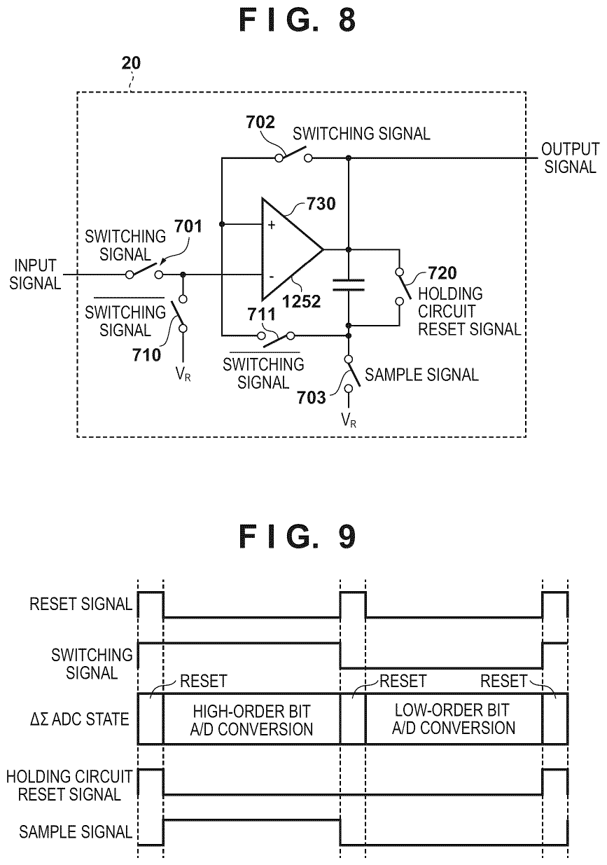

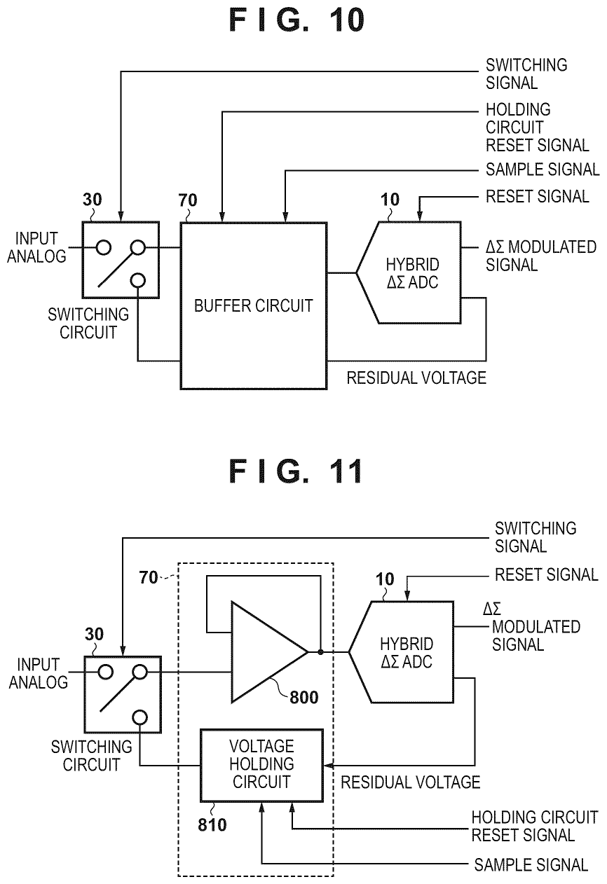

FIG. 8 shows an example of the arrangement of the residual voltage holding circuit 20. FIG. 9 is a timing chart showing an example of the operation of the residual voltage holding circuit 20. The residual voltage holding circuit 20 can be configured to include switches 701 and 702 controlled by a switching signal, a switch 703 controlled by a sample signal, switches 710 and 711 controlled by inverted switching signals, a switch 720 controlled by a holding circuit reset signal, an amplifier 730, and a sampling capacitor 740. Reference symbol V_{R} shown in FIG. 8 denotes, for example, a reference voltage such as the ground potential. In the residual voltage holding circuit 20, when the switching signal is at high level, the holding circuit reset signal is at high level, and the sample signal is at low level, the sampling capacitor 740 is reset. When the switching signal is at high level, the holding circuit reset signal is at low level, and the sample signal is at high level, a voltage substantially equivalent to the input signal is sampled in the sampling capacitor 740. The voltage sampled at this time becomes a residual voltage after 1-bit AD conversion corresponding to the high-order bits. When the switching signal is at low level, the holding circuit reset signal is at low level, and the sample signal is at high level, the voltage sampled in the sampling capacitor 740 is held. In this arrangement, implementing an input signal sampling operation and holding of a sampled input signal by using one amplifier can achieve low power consumption and a reduction in packaging area. The above has exemplified an operation example in which the switching signal is at high level during a high-order bit AD conversion period (during a first period), but limitation is not made thereto. Setting a switching signal at high level during an arbitrary period until the end of high-order bit AD conversion makes it possible to reduce the operation period of the residual voltage holding circuit 20 and achieve a reduction in power consumption.

The digital demodulation circuit 40 shown in FIG. 1 outputs a multi-bit demodulated signal by performing digital signal processing according to equation (2) with respect to a 1-bit time series ΔΣ modulated signal corresponding to the high-order bit string in the ΔΣ AD converter 10.

$$high - order bit demodulated signal = \frac{2}{M ( M + 1 )} {\sum }_{K = 1}^{M} {\sum }_{i = 1}^{K} D A C i n [ i ] \qquad ( 2 )$$

where M represents an oversampling ratio in AD conversion corresponding to the high-order bit string in the ΔΣ AD converter 10, and i represents the time index of the comparison result output on a time series basis. The digital demodulation circuit 40 outputs a multi-bit demodulated signal by performing digital signal processing according to equation (3) with respect to a 1-bit time series ΔΣ modulated signal corresponding to the low-order bit string in the ΔΣ AD converter 10.

$$low - order bit demodulated signal = \frac{2}{N ( N + 1 )} {\sum }_{K = 1}^{N} {\sum }_{i = 1}^{K} D A C i n [ i ] \qquad ( 3 )$$

where N represents an oversampling ratio in AD conversion corresponding to the low-order bit string in the ΔΣ AD converter 10, and i represents the time index of the comparison result output on a time series basis.

The reconstruction circuit 50 shown in FIG. 1 performs reconstruction processing according to equation (4) with respect to the high-order bit demodulated signal and the low-order bit demodulated signal. This reconstruction processing is normalized such that if the signal obtained by combining a high-order bit demodulated signal and a low-order bit demodulated signal is expressed in decimal notation (actually a binary signal), the maximum value in decimal is 1. If, for example, a signal with a value of 15 is generated in the decimal system, this reconstruction processing is performed to multiply the high-order bit demodulated signal and the low-order bit demodulated signal by 1/15. In this manner, the reconstruction circuit 50 obtains a final digital signal as the final A/D conversion result corresponding to M+L bits normalized assuming that the maximum value is 1 when expressed in decimal notation.

final digital signal

$$= high - order bit demodulated signal + \frac{2}{M ( M + 1 )} \cdot low - order bit demodulated signal \qquad ( 4 )$$

In this case, M and N may be the same or different.

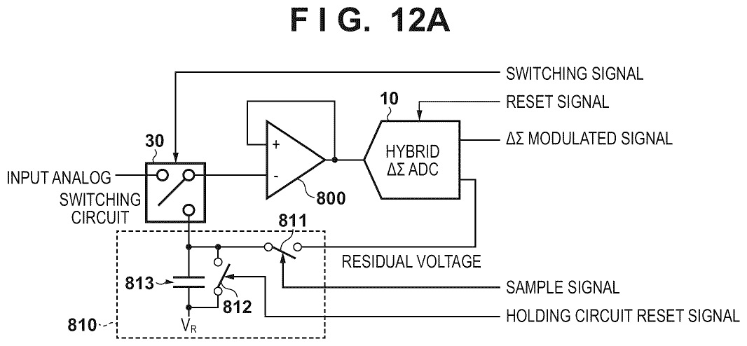

An AD conversion circuit 1 according to the second embodiment of the present disclosure will be described next with reference to FIGS. 10, 11, 12A, and 12B. FIG. 10 shows the AD conversion circuit 1 according to the present embodiment. Although not shown in FIG. 10, a digital demodulation circuit 40 and a reconstruction circuit 50 can be provided on the subsequent stage of a ΔΣ AD converter 10 as in the arrangement shown in FIG. 1.

As shown in FIG. 10, as compared with the arrangement example shown in FIG. 1, the AD conversion circuit 1 according to the present embodiment is provided with a buffer circuit 70 having a residual voltage holding function instead of the residual voltage holding circuit 20. A switching circuit 30 performs switching control between an input analog signal and an output signal from the buffer circuit 70 having a voltage holding function. The analog signal selected by the switching circuit 30 is input to the buffer circuit 70. The buffer circuit 70 outputs a buffered signal to the ΔΣ AD converter 10. The ΔΣ AD converter 10 is a second-order or higher order hybrid ΔΣ AD converter.

The switching circuit 30 provides the buffer circuit 70 with the analog signal provided to an input terminal IN during the first period and provides the buffer circuit 70 with the residual voltage output from the ΔΣ AD converter 10 at the end of the first period in the second period after the first period. The first period is a period in which AD conversion is performed to generate the high-order bit string of a digital signal corresponding to the analog signal provided to the input terminal IN. The second period is a period in which AD conversion is performed to generate the low-order bit string of the digital signal corresponding to the analog signal provided to the input terminal IN. The high-order bit string can be constituted by a plurality of bits. The low-order bit string can be constituted by a plurality of bits.

The buffer circuit 70 has a function of holding the residual voltage supplied from the ΔΣ AD converter 10 via the switching circuit 30 at the end of the first period throughout the second period. The buffer circuit 70 is controlled by a holding circuit reset signal and a sample signal. In the first period in which AD conversion is performed to generate the high-order bit string, the buffer circuit 70 buffers the analog signal supplied to the input terminal IN of the switching circuit 30 and output from the switching circuit 30 and outputs the buffered signal to the ΔΣ AD converter 10. The buffer circuit 70 holds the residual voltage output from the ΔΣ AD converter 10 at the end of the first period for the generation of the high-order bit string. Subsequently, in the second period, the buffer circuit 70 outputs a voltage obtained by buffering the held residual voltage, that is, a voltage corresponding to the residual voltage, to the ΔΣ AD converter 10. That is, the buffer circuit 70 has a function of holding a voltage signal corresponding to the residual voltage output from the integration circuit of the ΔΣ AD converter 10 at the end of the first period.

The second-order hybrid ΔΣ AD converter 10 includes a continuous-time integrator 110 on its input stage as exemplarily shown in FIGS. 3 and 4. If the continuous-time integrator 110 has a voltage/current conversion circuit, a DC voltage corresponding to an input analog signal voltage flows in the voltage/current conversion circuit. If, for example, a source follower circuit is used as a circuit for supplying an analog signal to the ΔΣ AD converter 10, a DC current value corresponding to the voltage value of the analog signal flows in addition to a bias current. Consequently, gain deviation occurs in the source follower circuit. This can cause a deterioration in the linearity of an analog signal. As in the present embodiment, arranging the buffer circuit 70 in the input path of an analog signal will suppress a DC current flowing in accordance with the voltage value of the analog signal in the source follower circuit. This can improve the linearity. In addition, standardizing the circuit for holding a residual voltage and the amplifier of the buffer circuit 70 can improve the linearity without increasing the number of circuit constituent elements and the power consumption.

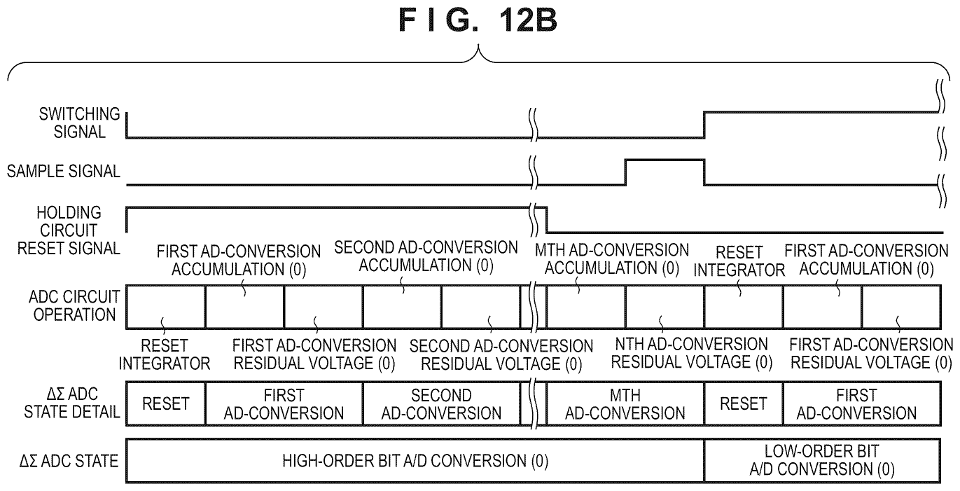

FIG. 11 shows a detailed arrangement example of the buffer circuit 70 having the residual voltage holding function. The buffer circuit 70 includes an amplifier 800 and a voltage holding circuit 810. The voltage holding circuit 810 is controlled by a holding circuit reset signal and a sample signal, holds the residual voltage supplied from the ΔΣ AD converter 10, and outputs the residual voltage. For example, the buffer circuit 70 can be implemented as a voltage follower arrangement by using the 2-input/1-output amplifier 800.

In the first period, the analog signal provided to the input terminal IN is buffered by using the amplifier 800. In the second period, the voltage held by the voltage holding circuit 810 at the end of the first period is held and buffered by using the amplifier 800, thereby generating a voltage signal.

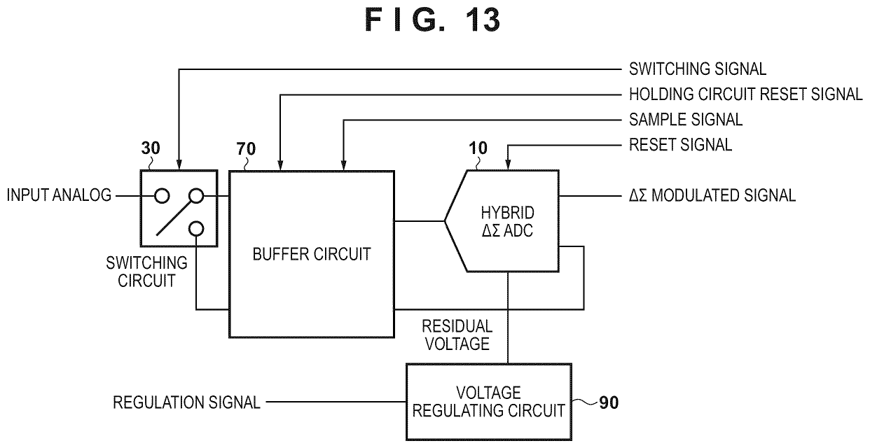

FIG. 12A shows an example of the arrangement of the buffer circuit 70 having a more specific residual voltage holding function. FIG. 12B shows the operation timing of the buffer circuit 70. The voltage holding circuit 810 can be configured to include switches 811 and 812 and a capacitor 813. Reference symbol V_{R} shown in FIG. 12A denotes, for example, a reference voltage such as the ground potential. In a period in which a switching signal is at low level, the analog signal supplied to the input terminal IN is supplied to the buffer circuit 70 formed by the amplifier 800 (voltage follower circuit), and the analog signal buffered by the voltage follower circuit is supplied to the ΔΣ AD converter 10. In the first period in which the ΔΣ AD converter 10 performs AD conversion for generating a high-order bit string, the voltage follower circuit keeps buffering the analog signal until the completion of integrator accumulation of AD conversion for the final bit of the high-order bit string. Subsequently, the sample signal is set to high level to accumulate a residual voltage in the capacitor 813. After the sample signal is set to low level, the accumulated residual voltage is held until the holding circuit reset signal is set to high level. In the second period in which AD conversion for generating a low-order bit string is performed, the switching circuit 30 supplies an output signal from the voltage holding circuit 810 to the ΔΣ AD converter 10. The holding circuit reset signal can be set to high level at the start of the first period in which AD conversion for generating a high-order bit string is performed and can be set to low level at an arbitrary time point before the final integrator accumulation operation in the first period.

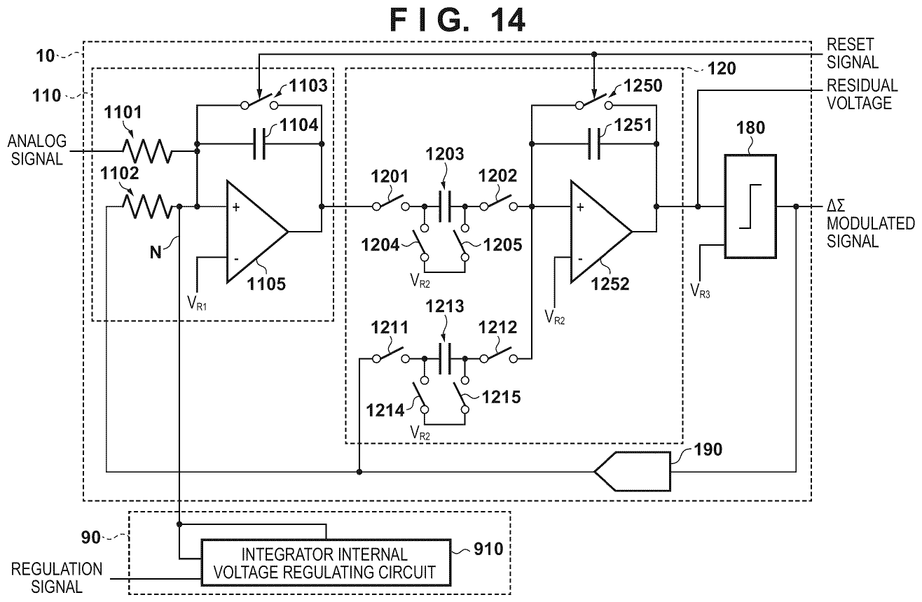

An AD conversion circuit 1 according to the third embodiment of the present disclosure will be described with reference to FIGS. 13 to 16. FIG. 13 shows the AD conversion circuit 1 according to the present embodiment. Although not shown in FIG. 13, a digital demodulation circuit 40 and a reconstruction circuit 50 can be arranged on a subsequent stage relative to a ΔΣ AD converter 10 as in the arrangement shown in FIG. 1. The AD conversion circuit 1 shown in FIG. 13 is based on the arrangement and operation shown in FIG. 10 but additionally includes a voltage regulating circuit 90.

The voltage regulating circuit 90 supplies a signal voltage substantially equivalent to a regulation signal to the ΔΣ AD converter 10 in accordance with the regulation signal. The voltage at an internal node in a period in which the ΔΣ AD converter 10 performs AD conversion is held by the voltage regulating circuit 90 within a range near the signal value of the regulation signal. Adding the circuit for regulating the voltage at the internal node within a predetermined range to the ΔΣ AD converter 10 as in this arrangement will provide the following merit in addition of merits described in the first and second embodiments. That is, even if the operating point of a buffer circuit 70 differs from the operating point of an internal voltage in the ΔΣ AD converter 10, the operating point of the internal voltage in the analog circuit in the ΔΣ AD converter 10 is adjusted within the range near the signal value of the regulation signal. This improves the linearity.

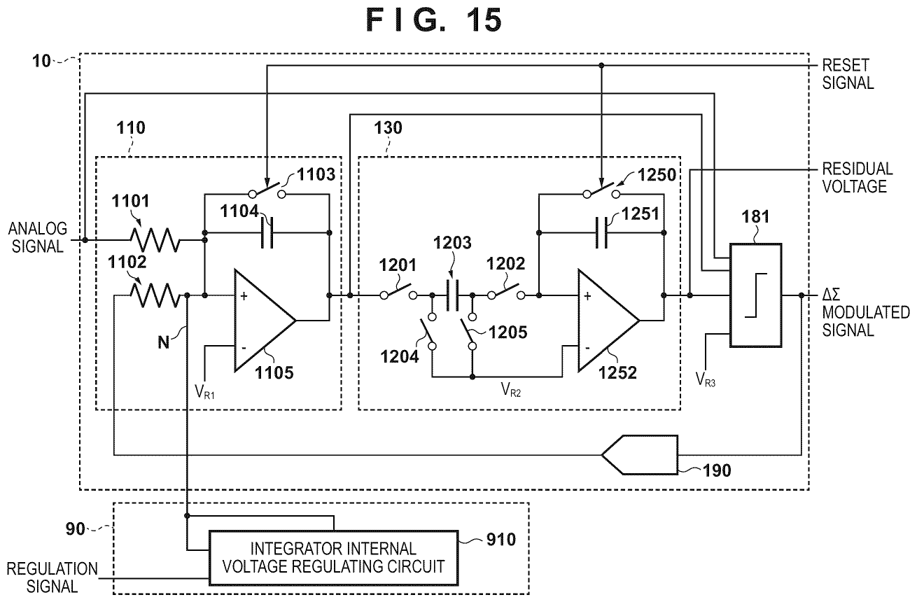

FIG. 14 shows a detailed arrangement example of the second-order hybrid ΔΣ AD converter 10 and the voltage regulating circuit 90. Similar to the arrangement shown in FIG. 3, the ΔΣ AD converter 10 can include a continuous-time integrator 110, a discrete-time integrator 120, a comparator 180, and a DA converter 190. The continuous-time integrator 110 can be configured to include resistors 1101 and 1102, a capacitor 1104, a switch 1103, and an amplifier 1105. The discrete-time integrator 120 can be configured to include capacitors 1203, 1213, and 1251, switches 1201, 1202, 1204, 1205, 1211, 1212, 1214, 1215, and 1250, and an amplifier 1252. The voltage regulating circuit 90 can be configured to include an integrator internal voltage regulating circuit 910. Reference symbols V_{R1} to V_{R3} shown in FIG. 14 denote, for example, reference voltages such as the ground potential. Although the arrangement shown in FIG. 14 is configured to supply different reference voltages in the respective circuit blocks, the voltage V_{R1} to V_{R3} may be the same voltage. The circuit operation of the ΔΣ AD converter 10 shown in FIG. 14 can be similar to that of the circuit exemplified by the arrangement example in FIGS. 1 and 10.

An output from the continuous-time integrator 110 is supplied to the discrete-time integrator 120, and an output from the discrete-time integrator 120 is supplied to the comparator 180. An output from the comparator 180 is supplied to the DA converter 190, and an output from the DA converter 190 is supplied to the resistor 1102 of the continuous-time integrator 110 and the switch 1211 of the discrete-time integrator 120. An output from the discrete-time integrator 120 is output as the residual voltage of the ΔΣ AD converter 10.

In the continuous-time integrator 110, an internal signal at an internal node N to which the resistors 1101 and 1102, the capacitor 1104, the switch 1103, and the amplifier 1105 are connected is supplied to the integrator internal voltage regulating circuit 910. A regulation signal is also supplied to the integrator internal voltage regulating circuit 910. This makes the integrator internal voltage regulating circuit 910 regulate the internal signal at the internal node N within a range near the signal value of the regulation signal input to the integrator internal voltage regulating circuit 910 (in other words, within a predetermined range).

FIG. 14 shows an example of the arrangement of a single-phase circuit.

However, even if the continuous-time integrator 110 and the discrete-time integrator 120 constitute a differential circuit, the voltage at the internal node can be regulated by a similar arrangement. In the case of a differential arrangement, a voltage input as a regulation signal is an in-phase mode signal, and the internal voltage regulated by the integrator internal voltage regulating circuit is the in-phase mode voltage of the continuous-time integrator 110.

In the arrangement example shown in FIG. 14, the AD conversion circuit 1 is configured as a second-order hybrid ΔΣ AD conversion circuit. According to the arrangement example shown in FIG. 14, in the ΔΣ AD converter 10, both the comparator 180 and the DA converter 190 have 1-bit configurations. However, the comparator 180 and the DA converter 190 may have multi-bit configurations, and circuits equivalent to the resistor 1102 of the continuous-time integrator 110 and the switches 1211, 1212, 1214, and 1215 and the capacitor 1213 of the discrete-time integrator 120 may be increased in accordance with the resolution of the comparator 180 and the DA converter 190, and the circuits may be connected in parallel. Making the comparator 180 and the DA converter 190 have multi-bit configurations makes it possible to increase the A/D conversion speed of the continuous-time ΔΣ AD converter 10. A third-order or higher order continuous-time ΔΣ AD converter may be configured by adding one or more discrete-time integrators between the discrete-time integrator 120 and the comparator 180. Increasing the number of integrators can increase the A/D conversion speed of the hybrid ΔΣ AD converter 10.

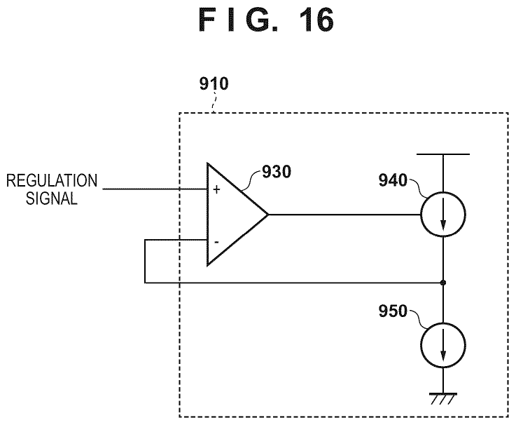

FIG. 15 shows a detailed arrangement example of the second-order hybrid ΔΣ AD converter 10 and the voltage regulating circuit 90 which is different from that shown in FIG. 14. The ΔΣ AD converter 10 shown in FIG. 15 additionally includes the voltage regulating circuit 90 (the integrator internal voltage regulating circuit 910) that regulates the voltage at the internal node of the continuous-time integrator 110 in addition to the arrangement shown in FIG. 4 which has the feedforward path. Reference symbols V_{R1} to V_{R3} shown in FIG. 15 denote, for example, reference voltages such as the ground potential. Although the arrangement shown in FIG. 15 is configured to supply different reference voltages in the respective circuit blocks, the voltage V_{R1} to V_{R3} may be the same voltage. The circuit operation of the ΔΣ AD converter 10 shown in FIG. 15 can be similar to that of the circuit exemplified by the arrangement example in FIGS. 1 and 10.

In the continuous-time integrator 110, an internal signal at the internal node N to which the resistors 1101 and 1102, the capacitor 1104, the switch 1103, and the amplifier 1105 are connected is supplied to the integrator internal voltage regulating circuit 910. A regulation signal is also supplied to the integrator internal voltage regulating circuit 910. This makes the integrator internal voltage regulating circuit 910 regulate the internal signal at the internal node N within a range near the signal value of the regulation signal input to the integrator internal voltage regulating circuit 910 (in other words, within a predetermined range).

FIG. 15 shows an example of the arrangement of a single-phase circuit. However, even if the continuous-time integrator 110 and the discrete-time integrator 120 constitute a differential circuit, the voltage at the internal node can be regulated by a similar arrangement. In the case of a differential arrangement, a voltage input as a regulation signal is an in-phase mode signal, and the internal voltage regulated by the integrator internal voltage regulating circuit is the in-phase mode voltage of the continuous-time integrator 110.

In the arrangement shown in FIG. 15, an output from the continuous-time integrator 110 and the analog signal supplied to the continuous-time integrator 110 are supplied to a 4-input comparator 181 in addition to an output from the discrete-time integrator 130 and the reference signal (the reference voltage V_{R3}). Supplying the signal input to the ΔΣ AD converter 10 to the comparator 181 can suppress the amplitudes of the signals output from the continuous-time integrator 110 and the discrete-time integrator 130 and suppress the influence of the nonlinearity of the amplifier 1105 and the amplifier 1252. This makes it possible to improve the nonlinearity strain characteristics of the ΔΣ AD converter 10.

In the arrangement example shown in FIG. 15, the AD conversion circuit 1 is configured as a second-order hybrid ΔΣ AD conversion circuit. In the arrangement example shown in FIG. 15, in the AD converter 10, both the comparator 181 and the DA converter 190 have 1-bit configurations. However, the comparator 181 and the DA converter 190 may have multi-bit configurations, and the resistor 1102 of the continuous-time integrator 110 may be increased in number in accordance with the resolution of the comparator 180 and the DA converter 190, and the resistors may be connected in parallel. Making the comparator 181 and the DA converter 190 have multi-bit configurations makes it possible to increase the A/D conversion speed of the ΔΣ AD converter 10. A third-order or higher order hybrid ΔΣ AD converter may be configured by adding one or more discrete-time integrators between the discrete-time integrator 120 and the comparator 181. Increasing the number of integrators can increase the A/D conversion speed of the hybrid ΔΣ AD converter 10.

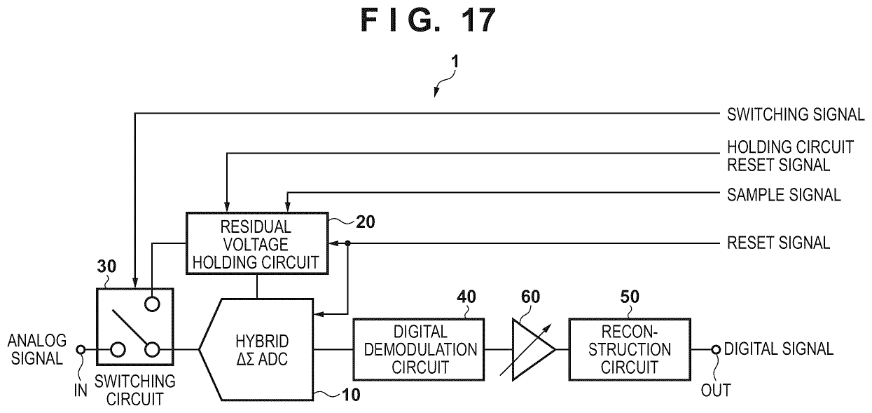

FIG. 16 shows a detailed arrangement example of the integrator internal voltage regulating circuit 910. The integrator internal voltage regulating circuit 910 can be configured to include an amplifier 930, a voltage control current source 940, and a current source 950. A regulation signal is supplied to the non-inverting input terminal of the amplifier 930, and the internal node N of the continuous-time integrator 110 can be connected to the inverting input terminal of the amplifier 930. The output of the amplifier 930 can be connected to the control terminal of the voltage control current source 940. One main terminal of the voltage control current source 940 is connected to the current source 950 and can be connected as a regulating target signal to the non-inverting input terminal of the amplifier 930. According to this arrangement, a regulating target signal is controlled to have a voltage near a regulation signal based on the negative feedback principle. With this control, the voltage at the internal node N of the continuous-time integrator 110 is regulated within a predetermined range. In this case, the voltage control current source 940 can be implemented by, for example, a PMOS transistor and the like. FIG. 16 shows an example of a circuit that controls the voltage at the internal node of a regulating target based on the negative feedback principle. Any circuit that implements a similar function can be used as the integrator internal voltage regulating circuit 910.

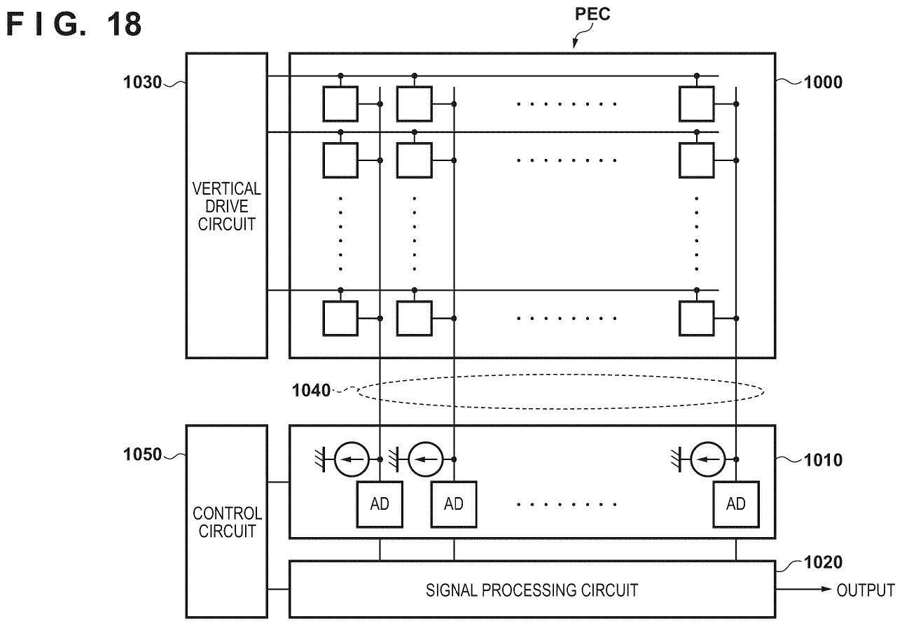

FIG. 17 shows an example of the arrangement of an AD conversion circuit 1 according to the fourth embodiment of the present disclosure. The AD conversion circuit 1 is configured as a 2-stage ΔΣ AD conversion circuit. The AD conversion circuit 1 converts the analog signal provided to an input terminal IN into a digital signal and outputs it from an output terminal OUT. The AD conversion circuit 1 can include a ΔΣ AD converter 10 and a switching circuit 30. The AD conversion circuit 1 can include a digital gain adjusting circuit 60 in addition to a residual voltage holding circuit 20, a digital demodulation circuit 40, and a reconstruction circuit 50.

The switching circuit 30 provides the ΔΣ AD converter 10 with the analog signal provided to the input terminal IN during the first period. In addition, the switching circuit 30 provides the ΔΣ AD converter 10 with a voltage signal corresponding to the voltage output from the integration circuit of the ΔΣ AD converter 10 at the end of the first period during the second period after the first period. The first period is a period in which AD conversion is performed to generate a high-order bit string of a digital signal corresponding to the analog signal provided to the input terminal IN. The second period is a period in which AD conversion is performed to generate a low-order bit string of a digital signal corresponding to the analog signal provided to the input terminal IN. The high-order bit string can be constituted by a plurality of bits. The low-order bit string can be constituted by a plurality of bits.

The residual voltage holding circuit 20 holds (samples) a voltage signal corresponding to the residual voltage output from the ΔΣ AD converter 10 at the end of the first period and provides the voltage signal to the switching circuit 30 in the second period. The residual voltage holding circuit 20 can be controlled by, for example, a holding circuit reset signal and a sample signal.

In the first period, the ΔΣ AD converter 10 performs AD conversion corresponding to a high-order bit string, and the switching circuit 30 supplies a voltage signal corresponding to the residual voltage held by the residual voltage holding circuit 20 at the end of the first period to the ΔΣ AD converter 10. Subsequently, in the second period, the ΔΣ AD converter 10 performs AD conversion corresponding to a low-order bit string. The digital demodulation circuit 40 demodulates the time-series ΔΣ modulated signal (high-order bit string) output from the ΔΣ AD converter 10 in the first period into a digital signal having a plurality of bits. In addition, the digital demodulation circuit 40 demodulates the time-series ΔΣ modulated signal (low-order bit string) output from the ΔΣ AD converter 10 in the second period into a digital signal having a plurality of bits. The reconstruction circuit 50 generates an output digital signal based on the digital signal of the high-order bit string and the digital signal of the low-order bit string, which are demodulated by the digital demodulation circuit 40. An internal signal in the ΔΣ AD converter 10, the voltage signal held by the residual voltage holding circuit 20, and an internal signal in the digital demodulation circuit 40 are reset before the start of the first period and before the start of the second period in accordance with reset signals.

The digital gain adjusting circuit 60 can be arranged between the digital demodulation circuit 40 and the reconstruction circuit 50. The digital gain adjusting circuit 60 can perform gain adjustment for the digital signal output from the digital demodulation circuit 40 and supply the digital signal having undergone the gain adjustment to the reconstruction circuit 50. The digital gain adjusting circuit 60 can be configured to perform gain adjustment for the digital signal of the low-order bit string output from the digital demodulation circuit 40 and not to perform gain adjustment for the digital signal of the high-order bit string output from the digital demodulation circuit 40. The digital gain (correction value) to be applied by the digital gain adjusting circuit 60 can be acquired in advance before AD conversion for an analog signal as an AD conversion target. For example, a correction value can be generated by inputting an analog signal with a reference value to the AD conversion circuit 1 and comparing the digital signal (expected value) that should be obtained with the digital signal actually output from the AD conversion circuit 1. In addition, in order to improve the correction accuracy, a correction value may be acquired by using analog signals with a plurality of different reference values.

In the residual voltage holding circuit 20, for example, errors unique to the circuit, such as a gain error caused by the finite gain of the amplification circuit, can occur. Such a gain error can cause errors from the logic values represented by equations (2) and (3) between the high-order bit demodulated signal and the low-order bit demodulated signal. This can cause nonlinear strain in the AD converter and lead to a deterioration in performance. Performing digital correction for a gain error in the residual voltage holding circuit by using this arrangement can improve the nonlinear strain characteristics.

FIG. 17 shows a circuit arrangement based on the AD conversion circuit 1 according to the first embodiment shown in FIG. 1. However, limitation is not made thereto, and the digital gain adjusting circuit 60 may be added to the circuit arrangements exemplified by the second and third embodiments.

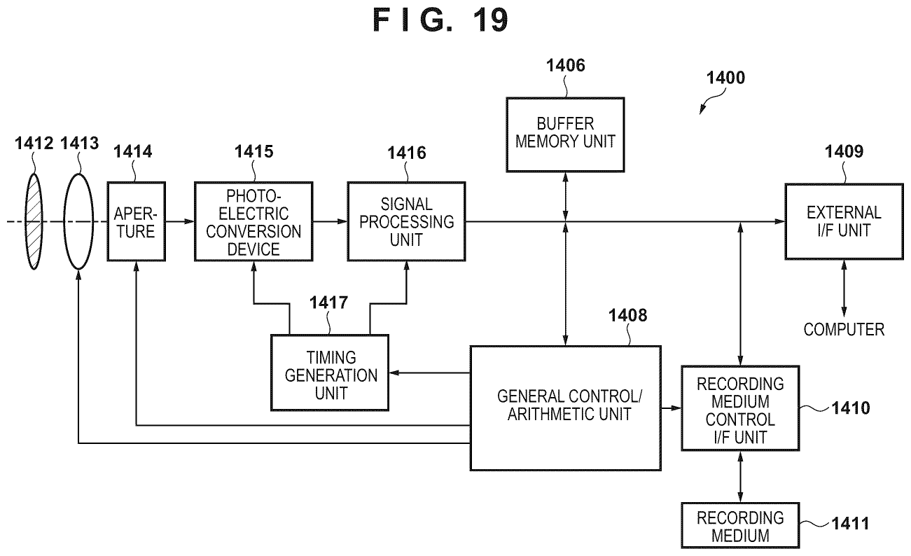

An application example of the AD conversion circuit 1 described above will be described below. FIG. 18 shows the arrangement of a photoelectric conversion device PEC using the AD conversion circuit 1 according to the present disclosure. The photoelectric conversion device PEC can be configured as a solid-state image capturing device that captures and outputs an image. Alternatively, the photoelectric conversion device PEC can be configured as a device that captures an image and outputs a signal obtained from the captured image.

The photoelectric conversion device PEC can include, for example, a pixel array (an array of a plurality of photoelectric conversion units) 1000, a vertical drive circuit 1030, a readout circuit (a current source and an AC conversion circuit) 1010, a control circuit 1050, and a signal processing circuit 1020. The readout circuit 1010 can include a plurality of current sources respectively connected to a plurality of vertical lines 1040 and an AD conversion circuit that A/D-converts signals output from pixels on a selected row to the plurality of vertical lines 1040. The above 2-stage ΔΣ AD conversion circuit (AD conversion circuit 1) can be applied to each AD conversion circuit provided for the readout circuit 1010. This makes it possible to reduce the size of the readout circuit 1010.

The photoelectric conversion device PEC can be configured to make the readout circuit 1010 read out a reset level from each pixel of the pixel array 1000 and the optical signal level generated by photoelectric conversion. The readout circuit 1010 can be configured to output a digital signal at the reset level and a digital signal at the optical signal level. The signal processing circuit 1020 can be configured to perform CDS processing with respect to the digital signal at the reset level and the digital signal at the optical signal level and output the signals having undergone the CDS processing. The pixel array 1000, the vertical drive circuit 1030, the readout circuit 1010, the control circuit 1050, and the signal processing circuit 1020 may be arranged on one substrate, may be stacked on each other upon being respectively arranged on a plurality of substrates, or may be separately formed on a plurality of chips. The photoelectric conversion device PEC can be, for example, a CMOS image sensor. Alternatively, the photoelectric conversion device PEC may be a front-illuminated sensor or back-illuminated sensor.

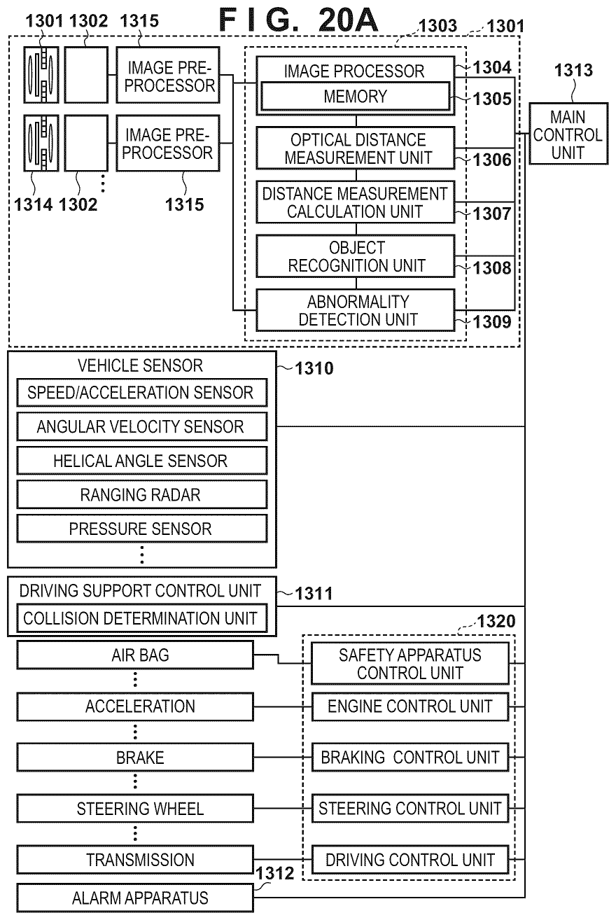

An example of a photoelectric conversion system using the photoelectric conversion device PEC will be described below. FIG. 19 is a block diagram showing the arrangement of a photoelectric conversion system 1400 according to an embodiment. The photoelectric conversion system 1400 according to the present embodiment includes a photoelectric conversion device 1415. In this case, the photoelectric conversion device PEC described above can be applied as the photoelectric conversion device 1415. The photoelectric conversion system 1400 can be used as, for example, an image capturing system. Specific examples of the image capturing system are a digital still camera, a digital camcorder, and a monitoring camera. FIG. 19 shows an example of the digital still camera (image capturing device) as the photoelectric conversion system 1400.

The photoelectric conversion system 1400 shown in FIG. 19 includes the photoelectric conversion device 1415, a lens 1413 for forming an optical image of an object on the photoelectric conversion device 1415, an aperture 1414 for changing the amount of light passing through the lens 1413, and a barrier 1412 for protecting the lens 1413. The lens 1413 and the aperture 1414 form an optical system for concentrating light to the photoelectric conversion device 1415. The photoelectric conversion system used for image capturing is also called an image capturing system.

The photoelectric conversion system 1400 includes a signal processor 1416 for processing an output signal output from the photoelectric conversion device 1415. The signal processor 1416 performs an operation of signal processing of performing various kinds of correction and compression for an input signal, as needed, thereby outputting the resultant signal. The photoelectric conversion system 1400 further includes a buffer memory unit 1406 for temporarily storing image data and an external interface unit (external I/F unit) 1409 for communicating with an external computer or the like. Furthermore, the photoelectric conversion system 1400 includes a recording medium 1411 such as a semiconductor memory for recording or reading out image capturing data, and a recording medium control interface unit (recording medium control I/F unit) 1410 for performing a recording or reading operation in or from the recording medium 1411. The recording medium 1411 may be incorporated in the photoelectric conversion system 1400 or may be detachable. In addition, communication with the recording medium 1411 from the recording medium control I/F unit 1410 or communication from the external I/F unit 1409 may be performed wirelessly.

Furthermore, the photoelectric conversion system 1400 includes a general control/arithmetic unit 1408 that performs various kinds of arithmetic operations and controls the entire digital still camera, and a timing generation unit 1417 that outputs various kinds of timing signals to the photoelectric conversion device 1415 and the signal processor 1416. Here, the timing signal and the like may be input from the outside, and the photoelectric conversion system 1400 need only include at least the photoelectric conversion device 1415 and the signal processor 1416 that processes an output signal output from the photoelectric conversion device 1415. The timing generation unit 1417 may be incorporated in the photoelectric conversion device. The general control/arithmetic unit 1408 and the timing generation unit 1417 may be configured to perform some or all of the control functions of the photoelectric conversion device 1415.

The photoelectric conversion device 1415 outputs an image signal to the signal processor 1416. The signal processor 1416 performs predetermined signal processing for the image signal output from the photoelectric conversion device 1415 and outputs image data. The signal processor 1416 also generates an image using the image signal. Furthermore, the signal processor 1416 may perform distance measurement calculation for the signal output from the photoelectric conversion device 1415. Note that the signal processor 1416 and the timing generation unit 1417 may be incorporated in the photoelectric conversion device. That is, each of the signal processor 1416 and the timing generation unit 1417 may be provided on a substrate on which pixels are arranged or may be provided on another substrate. An image capturing system capable of acquiring a higher-quality image can be implemented by forming an image capturing system using the photoelectric conversion device of each of the above-described embodiments.

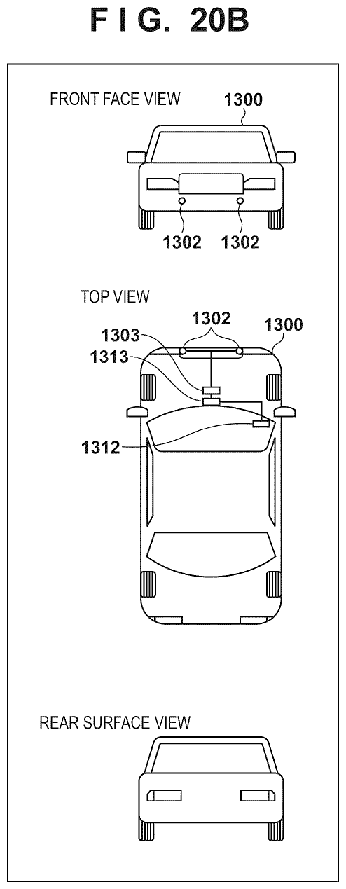

A photoelectric conversion system and a moving body according to another embodiment will be described with reference to FIGS. 20A and 20B. FIGS. 20A and 20B are schematic views showing an arrangement example of the photoelectric conversion system or an arrangement example of the moving body, respectively, according to present embodiment. In present embodiment, an example of an in-vehicle camera will be described as the photoelectric conversion system.

FIGS. 20A and 20B show examples of a vehicle system and a photoelectric conversion system that is incorporated in the vehicle system and performs image capturing. A photoelectric conversion system 1301 includes a photoelectric conversion device 1302, an image preprocessor 1315, an integrated circuit 1303, and an optical system 1314. In this case, the above photoelectric conversion device PEC can be applied to the photoelectric conversion device 1302. The optical system 1314 forms an optical image of an object on the photoelectric conversion device 1302. The photoelectric conversion device 1302 converts, into an electrical signal, the optical image of the object formed by the optical system 1314. The photoelectric conversion device 1302 can be the photoelectric conversion device described above. The image preprocessor 1315 performs predetermined signal processing for the signal output from the photoelectric conversion device 1302. The function of the image preprocessor 1315 may be incorporated in the photoelectric conversion device 1302. In the photoelectric conversion system 1301, at least two sets of the optical systems 1314, the photoelectric conversion devices 1302, and the image preprocessors 1315 are arranged, and an output from the image preprocessor 1315 of each set is input to the integrated circuit 1303.

The integrated circuit 1303 is an image capturing system application specific integrated circuit, and includes an image processor 1304 with a memory 1305, an optical distance measurement unit 1306, a distance measurement calculation unit 1307, an object recognition unit 1308, and an abnormality detection unit 1309. The image processor 1304 performs image processing such as development processing and defect correction for the output signal from each image preprocessor 1315. The memory 1305 temporarily stores a captured image, and stores the position of a defect in the captured image. The optical distance measurement unit 1306 performs focusing or distance measurement of an object. The distance measurement calculation unit 1307 calculates distance measurement information from a plurality of image data acquired by the plurality of photoelectric conversion devices 1302. The object recognition unit 1308 recognizes objects such as a vehicle, a road, a road sign, and a person. Upon detecting an abnormality of the photoelectric conversion device 1302, the abnormality detection unit 1309 notifies a main control unit 1313 of the abnormality.

The integrated circuit 1303 may be implemented by dedicated hardware, a software module, or a combination thereof. Alternatively, the integrated circuit 1303 may be implemented by a Field Programmable Gate Array (FPGA), an Application Specific Integrated Circuit (ASIC), or a combination thereof.

The main control unit 1313 comprehensively controls the operations of the photoelectric conversion system 1301, vehicle sensors 1310, a control unit 1320, and the like. A method in which the photoelectric conversion system 1301, the vehicle sensors 1310, and the control unit 1320 each individually include a communication interface and transmit/receive control signals via a communication network (for example, CAN standards) may be adopted without providing the main control unit 1313.

The integrated circuit 1303 has a function of transmitting a control signal or a setting value to each photoelectric conversion device 1302 by receiving the control signal from the main control unit 1313 or by its own control unit.

The photoelectric conversion system 1301 is connected to the vehicle sensors 1310 and can detect the traveling state of the self-vehicle such as the vehicle speed, the yaw rate, and the steering angle, the external environment of the self-vehicle, and the states of other vehicles and obstacles. The vehicle sensors 1310 also serve as a distance information acquisition unit that acquires distance information to a target object. Furthermore, the photoelectric conversion system 1301 is connected to a driving support control unit 1311 that performs various driving support operations such as automatic steering, adaptive cruise control, and anti-collision function. More specifically, with respect to a collision determination function, based on the detection results from the photoelectric conversion system 1301 and the vehicle sensors 1310, a collision with another vehicle or an obstacle is estimated or the presence/absence of a collision is determined. This performs control to avoid a collision when the collision is estimated or activates a safety apparatus at the time of a collision.

Furthermore, the photoelectric conversion system 1301 is also connected to an alarm device 1312 that generates an alarm to the driver based on the determination result of a collision determination unit. For example, if the determination result of the collision determination unit indicates that the possibility of a collision is high, the main control unit 1313 performs vehicle control to avoid a collision or reduce damage by braking, releasing the accelerator pedal, or suppressing the engine output. The alarm device 1312 sounds an alarm such as a sound, displays alarm information on the screen of a display unit such as a car navigation system or a meter panel, applies a vibration to the seat belt or a steering wheel, thereby giving an alarm to the user.

According to present disclosure, it is possible to provide a technique advantageous in reducing the circuit size of a ΔΣ AD conversion circuit.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-181234, filed Oct. 16, 2024, which is hereby incorporated by reference herein in its entirety.

What is claimed is:

1. An AD conversion circuit that converts an analog signal provided to an input terminal into a digital signal, the AD conversion circuit comprising:
a ΔΣ AD converter including an integration circuit configured to integrate a difference signal;
a switching circuit configured to perform switching to supply an analog signal supplied to the input terminal to the ΔΣ AD converter in a first period and supply a voltage signal corresponding to a voltage output from the integration circuit at an end of the first period to the ΔΣ AD converter in a second period after the first period; and
a holding circuit configured to hold the voltage signal corresponding to a voltage output from the integration circuit at the end of the first period and provide the voltage signal to the ΔΣ AD converter via the switching circuit in the second period,
wherein the integration circuit includes a continuous-time integrator and a discrete-time integrator connected to an output of the continuous-time integrator.

2. The AD conversion circuit according to claim 1, further comprising a comparator connected to an output of the discrete-time integrator and a DA converter connected to an output of the comparator,
wherein the comparator is configured to compare an output from the discrete-time integrator with a reference signal.

3. The AD conversion circuit according to claim 2, wherein the discrete-time integrator includes a first sampling circuit connected to an output of the continuous-time integrator and a second sampling circuit connected to an output of the DA converter.

4. The AD conversion circuit according to claim 2, wherein the discrete-time integrator includes a first sampling circuit connected to an output of the continuous-time integrator, and
the comparator is configured to compare an output from the continuous-time integrator and an analog signal supplied to the continuous-time integrator, in addition to an output from the discrete-time integrator, with the reference signal.

5. The AD conversion circuit according to claim 4, wherein the discrete-time integrator further includes a second sampling circuit connected to an output of the continuous-time integrator.

6. The AD conversion circuit according to claim 5, wherein an output from the continuous-time integrator is alternately sampled by the first sampling circuit and the second sampling circuit.

7. The AD conversion circuit according to claim 1, wherein the continuous-time integrator is a Gm-C integrator.

8. The AD conversion circuit according to claim 1, further comprising a buffer circuit configured to buffer an output from the switching circuit and supply the output to the ΔΣ AD converter.

9. The AD conversion circuit according to claim 8, wherein the buffer circuit includes an amplifier,
the analog signal supplied to the input terminal is buffered by using the amplifier in the first period, and
the voltage signal held in the holding circuit is held and buffered by using the amplifier in the second period.

10. The AD conversion circuit according to claim 1, further comprising a voltage regulating circuit configured to regulate a voltage at an internal node of the ΔΣ AD converter within a predetermined range.

11. The AD conversion circuit according to claim 10, wherein the voltage regulating circuit is configured to regulate a voltage at an internal node of the continuous-time integrator within a predetermined range.

12. The AD conversion circuit according to claim 1, further comprising:
a digital demodulation circuit configured to generate a digital signal of a high-order bit string based on an output from the ΔΣ AD converter in the first period and generate a digital signal of a low-order bit string based on an output from the ΔΣ AD converter in the second period; and
a reconstruction circuit configured to generate an output digital signal based on the digital signal of the high-order bit string and the digital signal of the low-order bit string.

13. The AD conversion circuit according to claim 12, further comprising a gain adjusting circuit arranged between the digital demodulation circuit and the reconstruction circuit.

14. The AD conversion circuit according to claim 13, wherein the gain adjusting circuit performs gain adjustment for the digital signal of the low-order bit string.

15. A photoelectric conversion device comprising:
a photoelectric conversion unit; and
the AD conversion circuit according to claim 1 and configured to convert an analog signal output from the photoelectric conversion unit into a digital signal.

16. An image capturing device comprising:
the photoelectric conversion device according to claim 15; and
a signal processor configured to process a signal output from the photoelectric conversion device.

17. A moving body comprising the image capturing device according to claim 16.

18. A method of driving an AD conversion circuit configured to convert an analog signal provided to an input terminal into a digital signal,
the AD conversion circuit comprising: a ΔΣ AD converter including an integration circuit configured to integrate a difference signal; a holding circuit; and a switching circuit configured to switch between connection between the input terminal and the ΔΣ AD converter and connection between the holding circuit and the ΔΣ AD converter,
the method comprising:
causing the switching circuit to connect between the input terminal and the ΔΣ AD converter to supply an analog signal supplied to the input terminal to the ΔΣ AD converter and causing the holding circuit to hold a voltage signal corresponding to a voltage output from the integration circuit; and
causing the switching circuit to connect between the holding circuit and the ΔΣ AD converter to supply a voltage signal held by the holding circuit at an end of the causing the switching circuit between the input terminal and the ΔΣ AD converter to the ΔΣ AD converter after the causing the switching circuit between the input terminal and the ΔΣ AD converter,
wherein the integration circuit includes a continuous-time integrator and a discrete-time integrator connected to an output of the continuous-time integrator.
